(19) United States
(12) Patent Application Publication
(10) Pub. No.: US 2026/0092966 A1
(43) Pub. Date: Apr. 2, 2026

(54) SEMICONDUCTOR DEVICE TESTING EQUIPMENT

(71) Applicant: Kee Bok SEO, Paju-si (KR)

(72) Inventor: Kee Bok SEO, Paju-si (KR)

(21) Appl. No.: 19/329,149

(22) Filed: Sep. 15, 2025

(30) Foreign Application Priority Data
Oct. 2, 2024 (KR) 10-2024-0133756
Nov. 7, 2024 (KR) 10-2024-0156719

(51) Int. Cl. G01R 31/28; G01R 1/073

(52) U.S. Cl. CPC G01R 31/2863; G01R 1/07357; G01R 1/07364

(57) ABSTRACT

A semiconductor device testing equipment comprises a test substrate having a first surface and a second surface opposing each other, and a plurality of substrate pads disposed on the first surface, a plurality of test pins respectively disposed on the plurality of substrate pads and supporting a semiconductor device, each of the test pins having first and second structures that are symmetrical with respect to an axis having a predetermined inclination from the first surface of the test substrate, and first to third elastic structures respectively extending along the plurality of test pins.

### PRIORITY STATEMENT

This application claims priority under 35 U.S.C. § 119 to Korean Patent Application No. 10-2024-0133756 on October 2, and No. 10-2024-0156719 filed on Nov. 7, 2024 in the Korean Intellectual Property Office (KIPO), the contents of which are herein incorporated by reference in their entirety.

### BACKGROUND

### 1. Field

Example embodiments relate to a semiconductor device testing equipment. More particularly, example embodiments relate to a semiconductor device testing equipment for testing a reliability of a semiconductor device.

### 2. Description of the Related Art

Generally, high-power semiconductor devices may be packaged in a lead-type package form. For testing the high-power semiconductor device having the lead-type package form, special custom-made pins in a solid structure, rather than pogo pin-type testing devices, may be used to enhance test reliability. These custom-made pins may be formed using metallic materials and may include elastic materials such as silicone or rubber, including synthetic elastomers of silicone. Since such custom-made pins require specialized structural designs, their manufacturing period tends to be long, and the production process is complex, which may lead to increased manufacturing costs. Furthermore, due to their structural characteristics, the custom-made pins typically need to be discarded after a single use.

### SUMMARY

Example embodiments provide a semiconductor device testing equipment including a plurality of test pins having structures capable of maintaining test performance while enabling multiple tests to be performed on semiconductor devices.

According to example embodiments, a semiconductor device testing equipment comprises a test substrate having a first surface and a second surface opposing each other, and a plurality of substrate pads disposed on the first surface, a plurality of test pins respectively disposed on the plurality of substrate pads and supporting a semiconductor device, each of the test pins having first and second structures that are symmetrical with respect to an axis having a predetermined inclination from the first surface of the test substrate, and first to third elastic structures respectively extending along the plurality of test pins.

According to example embodiments, the first structures are respectively in contact with the plurality of substrate pads and respectively have first grooves configured to fix the first elastic structure, the second structures respectively have second grooves that are symmetrical to the first grooves with respect to the axis, the plurality of test pins respectively have third grooves on the axis along which the first and second structures are extended, and the second elastic structure extends along the third grooves between the plurality of test pins and the test substrate.

According to example embodiments, the semiconductor device testing equipment further includes a third elastic structure extending along the second grooves.

According to example embodiments, the plurality of test pins further include fourth grooves disposed on the axis opposite to the third grooves, and further include a fourth elastic structure extending along the fourth grooves.

According to example embodiments, the predetermined inclination is within a range of 30 degrees to 60 degrees.

According to example embodiments, each of the plurality of test pins includes a first pattern provided on the first structure, and a second pattern provided on the second structure and different from the first pattern.

According to example embodiments, each of the first to third elastic structures has a diameter within a range of 0.5 mm to 1.2 mm.

According to example embodiments, the semiconductor device is formed by a lead-type packaging process.

According to example embodiments, a semiconductor device testing equipment may include a test substrate having a first surface and a second surface opposing each other, and a plurality of substrate pads disposed on the first surface, a plurality of test pins respectively disposed on the plurality of substrate pads and supporting a semiconductor device, each of the test pins having first and second structures that are symmetrical with respect to an axis having a predetermined inclination from the first surface of the test substrate, and first to third elastic structures respectively extending along the plurality of test pins.

Thus, the plurality of test pins may be in contact with the plurality of substrate pads through the first structures, and the test substrate may be electrically connected to the semiconductor device through the plurality of test pins. Since the first and second structures constituting the plurality of test pins are symmetrical with respect to the axis, the plurality of test pins may be rotated around the axis after a reliability test on the semiconductor device has been completed. In this case, the plurality of test pins may contact the plurality of substrate pads through the second structures, and the test substrate may be electrically connected to another semiconductor device through the plurality of test pins to perform a reliability test.

Since the plurality of test pins perform the reliability test on different semiconductor devices, the reliability test may be performed multiple times using the same test pins. Accordingly, it is possible to reduce the manufacturing cost and time required to produce the plurality of test pins and improve process efficiency.

Also, the first and second elastic structures may respectively extend along the plurality of test pins. The first elastic structure may extend along the plurality of test pins to prevent twisting or misalignment between the test pins, and the second elastic structure may be disposed between the plurality of test pins and the test substrate to absorb external forces applied to the test pins and improve the accuracy of the reliability test.

### BRIEF DESCRIPTION OF THE DRAWINGS

Example embodiments will be more clearly understood from the following detailed description taken in conjunction with the accompanying drawings. FIGS. 1 to 7 represent non-limiting, example embodiments as described herein.

FIG. 1 is a cross-sectional view illustrating a semiconductor device testing equipment in accordance with example embodiments.

FIG. 2 is a perspective view illustrating a plurality of test pins supporting a semiconductor device.

FIG. 3 is a perspective view illustrating a test pin and a plurality of elastic structures.

FIG. 4 is a view illustrating a reusable test pin and a plurality of elastic structures.

FIG. 5 is a cross-sectional view illustrating a semiconductor device testing equipment in accordance with example embodiments.

FIG. 6 is a perspective view illustrating a test pin and a plurality of elastic structures.

FIG. 7 is a view illustrating a reusable test pin and a plurality of elastic structures.

### DETAILED DESCRIPTION OF EXAMPLE EMBODIMENTS

Hereinafter, example embodiments will be explained in detail with reference to the accompanying drawings.

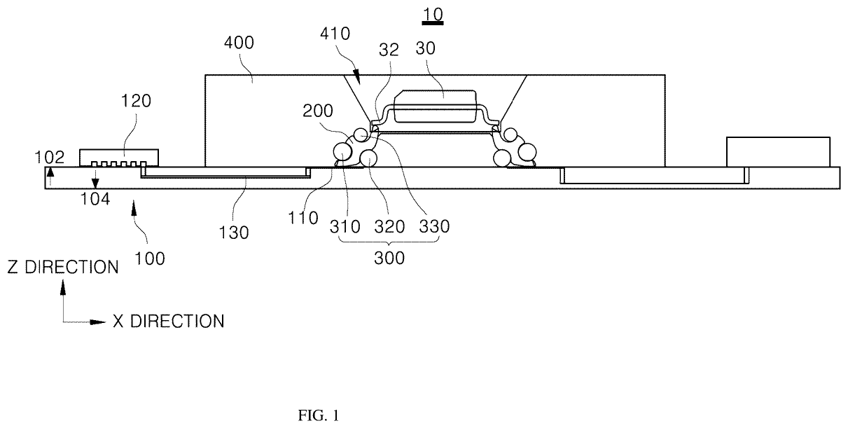

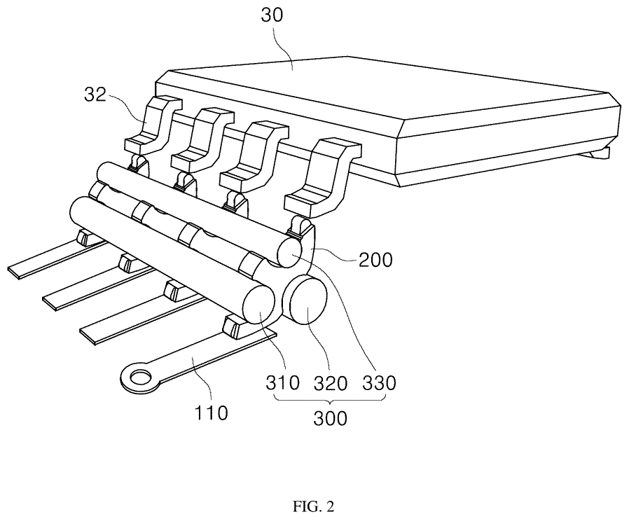

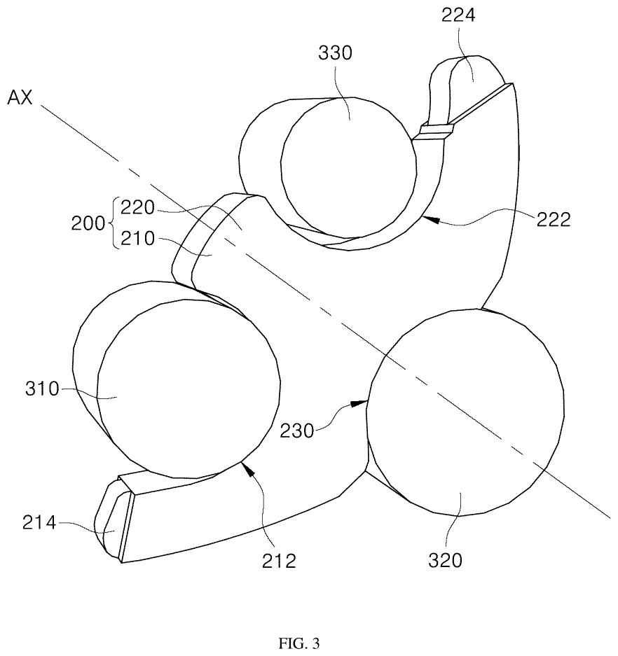

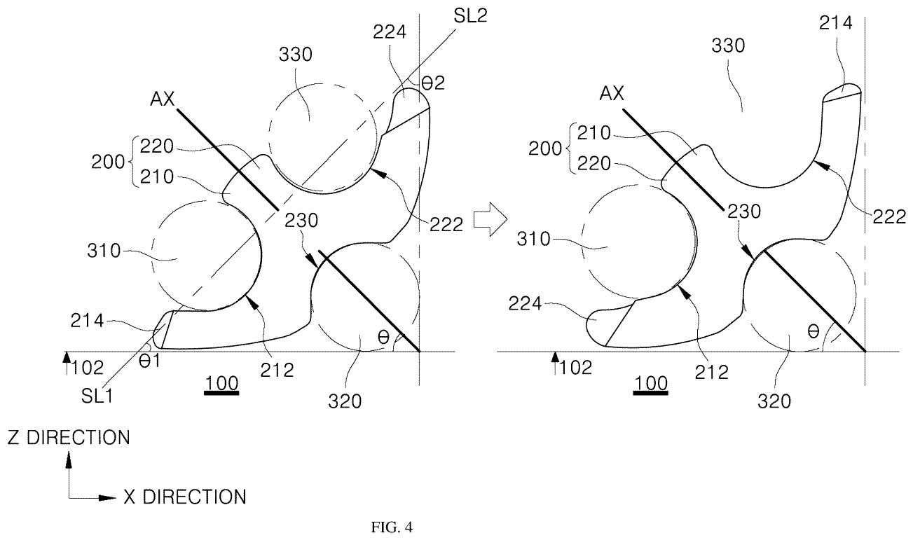

FIG. 1 is a cross-sectional view illustrating a semiconductor device testing equipment in accordance with example embodiments. FIG. 2 is a perspective view illustrating a plurality of test pins supporting a semiconductor device. FIG. 3 is a perspective view illustrating a test pin and a plurality of elastic structures. FIG. 4 is a view illustrating a reusable test pin and a plurality of elastic structures.

Referring to FIGS. 1 to 4, a semiconductor device testing equipment 10 may include a test substrate 100 having a plurality of substrate pads 110, a plurality of test pins 200 respectively disposed on the plurality of substrate pads 110, and a plurality of elastic structures 300 respectively extending along the plurality of test pins 200. The plurality of elastic structures 300 may include a first elastic structure 310 and a second elastic structure 320. The semiconductor device testing equipment 10 may further include a frame 400 on the test substrate 100 to cover the plurality of test pins 200, the plurality of elastic structures 300, and a semiconductor device 30. The plurality of elastic structures 300 may further include a third elastic structure 330.

The semiconductor device testing equipment 10 may support the semiconductor device 30 through the plurality of test pins 200, and may perform a reliability test on the semiconductor device 30 that is electrically connected to the test substrate 100 through the plurality of test pins 200. The semiconductor device 30 may be disposed in a receiving space 410 provided within the frame 400 on the test substrate 100, and the semiconductor device testing equipment 10 may perform the reliability test.

In exemplary embodiments, the semiconductor device 30 may be formed by a lead-type packaging process. The semiconductor device 30 may include a high-power, high-performance semiconductor substrate. The semiconductor device 30 may include conductive structures 32 configured to be electrically connected to external devices.

For example, the semiconductor device 30 may include packages such as DFN (Dual Flat No-lead), QFN (Quad Flat No-lead), SOIC (Small Outline Integrated Circuit), and TSSOP (Thin Shrink Small Outline Package). The semiconductor device 30 may also include packages such as TO-220 (Transistor Outline Package 220), TO-3 (Transistor Outline Package 3), TO-247, TO-92, DIP (Dual In-line Package), and SIP (Single In-line Package).

In exemplary embodiments, the test substrate 100 may have a first surface 102, and a second surface 104 opposing the first surface 102. The test substrate 100 may include the plurality of substrate pads 110 exposed from the first surface 102.

In exemplary embodiments, the test substrate 100 may include test circuits for performing the reliability test on the semiconductor device 30, and test terminals 120 electrically connected to the test circuits. For example, the test substrate 100 may be connected to an external device to receive power and exchange data. The test substrate 100 may be understood as an electronic substrate configured to test the reliability of the semiconductor device 30.

The test terminals 120 may include elements such as transistors and diodes. The test terminals 120 may constitute circuit elements. Therefore, the test substrate 100 may be referred to as a semiconductor device in which a plurality of circuit elements are formed therein.

For example, the test substrate 100 may include a semiconductor material such as silicon, germanium, or silicon-germanium, or may include a group III-V compound semiconductor such as gallium phosphide (GaP), gallium arsenide (GaAs), or gallium antimonide (GaSb). In some embodiments, the test substrate 100 may be a Silicon-On-Insulator (SOI) substrate or a Germanium-On-Insulator (GOI) substrate.

In exemplary embodiments, the test substrate 100 may include a redistribution layer. The redistribution layer may include a plurality of insulating films and redistribution wirings 130 provided in the insulating films. The redistribution layer may have an upper surface and a lower surface opposing each other. The plurality of substrate pads 110 may be exposed from the upper surface of the redistribution layer. For example, the redistribution wirings 130 may be formed through a plating process, an electroless plating process, or a vapor deposition process. The redistribution wirings 130 may include copper (Cu), aluminum (Al), tungsten (W), nickel (Ni), molybdenum (Mo), gold (Au), silver (Ag), chromium (Cr), tin (Sn), and titanium (Ti).

The insulating films may include polymers or dielectric layers. The insulating films may include silicon oxide, carbon-doped silicon oxide, or silicon carbon nitride (SiCN). The insulating films may be formed by vapor deposition or spin coating processes. The insulating films may have openings that expose the upper surfaces of the substrate pads 110. For example, the substrate pads 110 may include copper (Cu), aluminum (Al), tungsten (W), nickel (Ni), molybdenum (Mo), gold (Au), silver (Ag), chromium (Cr), tin (Sn), and titanium (Ti).

The plurality of substrate pads 110 may be electrically connected to the redistribution wirings 130 of the redistribution layer, and may be electrically connected to the test terminals 120 through the redistribution wirings 130. The plurality of substrate pads 110 may electrically connect the semiconductor device 30, which is disposed on the plurality of test pins 200, to the test terminals 120 via the redistribution wirings 130. The test substrate 100 may perform the reliability test on the semiconductor device 30 through the substrate pads 110 and the plurality of test pins 200.

In exemplary embodiments, the plurality of test pins 200 may be provided on the test substrate 100. The plurality of test pins 200 may be respectively disposed on the substrate pads 110 of the test substrate 100. The plurality of test pins 200 may support the semiconductor device 30, which is the target of the reliability test, on the test substrate 100.

The plurality of test pins 200 may include a conductor and may electrically connect the semiconductor device 30 to the test substrate 100. The plurality of test pins 200 may be provided on the substrate pads 110 of the test substrate 100 to support the semiconductor device 30. The plurality of test pins 200 may electrically connect the semiconductor device 30 and the test terminals 120 in conjunction with the substrate pads 110 and the redistribution wirings 130.

The plurality of test pins 200 may have a predetermined thickness. The predetermined thickness may fall within a range sufficient to carry an adequate amount of current and voltage. Since the predetermined thickness enables the delivery of sufficient current and voltage, the plurality of test pins 200 may offer higher testing efficiency than pogo pins. For example, the predetermined thickness may be within a range of 0.1 mm to 0.4 mm. The plurality of test pins 200 may be formed of silicon or the like, and may include an elastomer having elasticity. The plurality of test pins 200 may include copper (Cu), aluminum (Al), tungsten (W), nickel (Ni), molybdenum (Mo), gold (Au), silver (Ag), chromium (Cr), tin (Sn), and titanium (Ti).

In exemplary embodiments, each of the plurality of test pins 200 may have a first structure 210 and a second structure 220 extending from the first structure 210. The first structure 210 and the second structure 220 may constitute the test pin. The plurality of test pins 200 may be referred to as anchor pins.

Each of the plurality of test pins 200 may be inclined on the test substrate 100 to have a predetermined inclination angle (θ) from the first surface 102 of the test substrate 100. In the present disclosure, a thickness direction of the test substrate 100 is defined as the vertical direction (Z-direction), and a width direction perpendicular to the thickness direction is defined as the horizontal direction (X-direction). The horizontal direction (X-direction) may be a direction extending along the first surface 102. For example, the predetermined inclination angle (θ) may be within a range of 30 degrees to 60 degrees.

The first structures 210 and the second structures 220 may be provided to be symmetrical with respect to an axis AX having the predetermined inclination angle θ from the first surface 102. The first structures 210 and the second structures 220 may extend in opposite directions along the axis AX.

Since the first structures 210 and the second structures 220 are provided symmetrically with respect to the axis AX having the predetermined inclination angle θ from the first surface 102, the plurality of test pins 200 may be configured to rotate about the axis AX after the first reliability test is performed. The plurality of test pins 200 may perform a second reliability test after the first reliability test is completed.

Since the first structures 210 and the second structures 220 are symmetrically arranged with respect to the axis AX, the plurality of test pins 200 may be rotated about the axis AX and repositioned on the substrate pads 110 of the test substrate 100, thereby enabling the second reliability test to be conducted. Since the plurality of test pins 200 perform the reliability test multiple times, it may not be necessary to replace the test pins 200 each time the reliability test is conducted. Since the test pins 200 are capable of performing the reliability test at least twice, the manufacturing cost for producing the test pins 200 may be reduced. Furthermore, since the first structures 210 and the second structures 220 are provided symmetrically with respect to the axis AX, the same testing quality may be maintained even when the reliability test is conducted multiple times.

When the plurality of test pins 200 are rotated about the axis AX and repositioned on the substrate pads 110 of the test substrate 100, the contact area of each of the test pins 200 on the substrate pads 110 may vary. For example, the first structure 210 may contact the substrate pad 110 with a first contact area, and after the test pin 200 is rotated, the second structure 220 may contact the substrate pad 110 with a second contact area that is different from the first contact area.

In exemplary embodiments, each of the first structures 210 may contact the corresponding substrate pad 110 during the first reliability test. The first structures 210 may also fix the first elastic structure 310 during the first reliability test.

The first structures 210 may fix the third elastic structure 330 during the second reliability test. Alternatively, during the second reliability test, the first structures 210 may be provided such that they are not fixed to any of the elastic structures and are instead exposed outward.

The first structure 210 may have a first groove 212 configured to fix the first elastic structure 310 during the first reliability test. The plurality of test pins 200 may be arranged along the substrate pads 110 of the test substrate 100, and the first structures 210 of the test pins 200 may commonly fix the first elastic structure 310 through the first grooves 212 during the first reliability test.

The first structure 210 may fix the third elastic structure 330 through the first groove 212 during the second reliability test. The plurality of test pins 200 may be arranged along the substrate pads 110 of the test substrate 100, and the first structures 210 of the test pins 200 may commonly fix the third elastic structure 330 through the first grooves 212 during the second reliability test. Alternatively, the first structures 210 may be provided such that they are not fixed to the third elastic structures during the second reliability test and are exposed outward.

The first groove 212 of the first structure 210 may have a shape corresponding to the first elastic structure 310 or the third elastic structure 330. The first groove 212 of the first structure 210 may fix the first elastic structure 310 or the third elastic structure 330 through the corresponding shape. The first groove 212 of the first structure 210 may be provided to face upward, opposite to the test substrate 100. For example, the first groove 212 may have a circular groove shape. The first groove 212 may also include, without limitation, a triangular, rectangular, or pentagonal groove shape.

In exemplary embodiments, the second structures 220 may fix the third elastic structure 330 during the first reliability test. Alternatively, the second structures 220 may be provided to be exposed outward during the first reliability test, without fixing any of the elastic structures.

Each of the second structures 220 may contact a respective substrate pad 110 during the second reliability test. The second structures 220 may fix the first elastic structure 310 during the second reliability test.

The second structures 220 may respectively have second grooves 222 that are symmetrical to the first grooves 212 of the first structures 210 with respect to the axis AX. The second structure 220 may fix the third elastic structure 330 through the second groove 222 during the first reliability test. The plurality of test pins 200 may be arranged along the substrate pads 110 of the test substrate 100, and the second structures 220 of the test pins 200 may fix the third elastic structure 330 through the second grooves 222 during the first reliability test. Alternatively, the second structures 220 may be provided to be exposed outward without fixing the third elastic structure during the first reliability test.

The second structure 220 may fix the first elastic structure 310 through the second groove 222 during the second reliability test. The plurality of test pins 200 may be arranged along the substrate pads 110 of the test substrate 100, and the second structures 220 of the test pins 200 may fix the first elastic structure 310 through the second grooves 222 during the second reliability test.

The second groove 222 of the second structure 220 may have a shape corresponding to the first elastic structure 310 or the third elastic structure 330. The second groove 222 may fix the first elastic structure 310 or the third elastic structure 330 through the corresponding shape. The second groove 222 of the second structure 220 may be provided to face upward, opposite to the test substrate 100. For example, the second groove 222 may have a circular groove shape. The second groove 222 may also include, without limitation, a triangular, rectangular, or pentagonal groove shape.

In exemplary embodiments, each of the plurality of test pins 200 may include a third groove 230 provided along the axis AX in which the first structure 210 and the second structure 220 extend. The third grooves 230 may fix the second elastic structure 320 during the first and second reliability tests. The third grooves 230 may be provided between the plurality of test pins 200 and the test substrate 100 to hold the second elastic structure 320 in place.

The third grooves 230 may be provided symmetrically with respect to the axis AX. The plurality of test pins 200 may be arranged along the substrate pads 110 of the test substrate 100, and the second elastic structure 320 may be commonly fixed through the third grooves 230 during the first and second reliability tests.

The third grooves 230 of the test pins 200 may have a shape corresponding to the second elastic structure 320. The third grooves 230 may fix the second elastic structure 320 through the corresponding shape. The third grooves 230 may be provided to face the first surface 102 of the test substrate 100. For example, the third groove 230 may have a circular groove shape, or alternatively, a triangular, rectangular, or pentagonal groove shape without limitation.

In exemplary embodiments, each of the test pins 200 may further include a first pattern 214 and a second pattern 224. The first pattern 214 may be provided on the first structure 210, and the second pattern 224 may be provided on the second structure 220. The first pattern 214 and the second pattern 224 may have different shapes.

Since the first pattern 214 and the second pattern 224 have different shapes, the orientation of the test pins 200 may be determined even after rotation about the axis AX. Specifically, during the first reliability test, the first structure 210 contacting the substrate pad 110 may be identified by the first pattern 214, and during the second reliability test, the second structure 220 contacting the substrate pad 110 may be identified by the second pattern 224.

The first and second reliability tests may be distinguished by the first pattern 214 and the second pattern 224 of the test pins 200. Once the first reliability test is completed, the first and second structures 210 and 220 may be identified through the first pattern 214 and the second pattern 224.

Since the first and second structures 210 and 220 are identified through the first pattern 214 and the second pattern 224, the test pins 200 may be appropriately arranged, thereby improving an accuracy of the reliability test.

For example, the first pattern 214 may be a first step recessed from the outer surface of the first structure 210, and the second pattern 224 may be a second step recessed from the outer surface of the second structure 220. The first and second steps may have different depths.

In exemplary embodiments, the angle between the horizontal direction (X-direction) and a first line SL1 extending from the end of the first structure 210 toward the axis AX may be defined as a first angle θ1. The angle between the vertical direction (Z-direction) and a second line SL2 extending from the end of the second structure 220 toward the axis AX may be defined as a second angle θ2. For example, the first line SL1 and the second line SL2 may intersect or be parallel to each other. The difference between the first angle θ1 and the second angle θ2 may be within a range of 0 to 20 degrees.

In exemplary embodiments, the plurality of elastic structures may include the first elastic structure 310 and the second elastic structure 320. The plurality of elastic structures may further include the third elastic structure 330. The plurality of elastic structures may position the plurality of test pins 200 in proper locations during the reliability test.

The plurality of elastic structures may include an insulator. The insulator may block current between the plurality of test pins 200. Since the insulator blocks the current between the plurality of test pins 200, the test pins 200 may electrically connect the substrate pads 110 and the conductive structures 32 of the semiconductor device 30 during the reliability test. For example, the insulator may include a polymer or a dielectric material. The insulator may include silicon oxide, carbon-doped silicon oxide, silicon carbon nitride (SiCN), or the like.

The first elastic structure 310 may extend along the first grooves 212 of the first structures 210 during the first reliability test. The first elastic structure 310 may be fixed by the first grooves 212 of the first structures 210 during the first reliability test. The first elastic structure 310 may extend along the second grooves 222 of the second structures 220 during the second reliability test. The second elastic structure 320 may be fixed by the second grooves 222 of the second structures 220 during the second reliability test.

The first elastic structure 310 may have elasticity. Due to this elasticity, when the test pins 200 are pressed by the semiconductor device 30 or the frame 400, the first elastic structure 310 may buffer rotational force generated between the test pins 200 and stably support them. For example, a diameter of the first elastic structure 310 may be in a range of 0.5 mm to 1.2 mm.

The second elastic structure 320 may extend along the third grooves 230 between the test pins 200 and the test substrate 100. The second elastic structure 320 may extend along the third grooves 230 of the test pins 200 during the first and second reliability tests. The second elastic structure 320 may be fixed by the third grooves 230 of the test pins 200 during the first and second reliability tests. The second elastic structure 320 may be provided to be compressed between the test pins 200 and the test substrate 100 during the reliability tests.

The second elastic structure 320 may also have elasticity. Because of this elasticity, even when the test pins 200 are pressed by the semiconductor device 30 or the frame 400, the second elastic structure 320 may provide vertical force (Z-direction) toward the test pins 200 on the test substrate 100, thereby stably supporting the test pins 200. For example, the diameter of the second elastic structure 320 may be in a range of 0.5 mm to 1.2 mm.

The third elastic structure 330 may extend along the second grooves 222 of the second structures 220 during the first reliability test. The third elastic structure 330 may be fixed by the second grooves 222 of the second structures 220 during the first reliability test. During the second reliability test, the third elastic structure 330 may extend along the first grooves 212 of the first structures 210 and be fixed thereby.

The third elastic structure 330 may have elasticity. Due to this elasticity, even when the test pins 200 are pressed by the semiconductor device 30 or the frame 400, the third elastic structure 330, together with the first elastic structure 310, may buffer rotational force generated between the test pins 200 and stably support them. The third elastic structure 330 may reinforce the fixing of the test pins 200 together with the first and second elastic structures 310 and 320.

Since the first to third elastic structures 310, 320, and 330 jointly fix the plurality of test pins 200, they may enhance a restoring force of the test pins 200. These elastic structures may also increase the usable lifetime of the test pins 200 and maintain their alignment uniformly. For example, a diameter of the third elastic structure 330 may be in a range of 0.5 mm to 1.2 mm.

In exemplary embodiments, the semiconductor device testing equipment 10 may further include a frame 400. The frame 400 may cover the test pins 200, the elastic structures 300, and the semiconductor device 30 on the test substrate 100. The frame 400 may be installed on the test substrate 100.

The frame 400 may have a receiving space 410 for accommodating the test pins 200, the elastic structures 300, and the semiconductor device 30. During the reliability test, the frame 400 may protect the test pins 200, the elastic structures 300, and the semiconductor device 30 disposed in the receiving space 410 from external shocks.

During the reliability test, the frame 400 may apply pressure to the test pins 200. The test pins 200 may be more stably positioned under the pressure of the frame 400. The elastic structures 300 disposed between the test pins 200 and the frame 400 may absorb the pressure applied by the frame 400 and help maintain the stable placement of the test pins 200.

Specifically, the frame 400 may apply force in the vertical direction (Z-direction) to the test pins 200. The first and third elastic structures 310 and 330 may be connected across the test pins 200 to buffer rotational force generated between the pins. The second elastic structure 320 may provide elastic force between the test pins 200 and the test substrate 100 to stably support the test pins 200.

As described above, the test pins 200 may contact the substrate pads 110 through the first structure 210, and the test substrate 100 may be electrically connected to the semiconductor device 30 via the test pins 200. Since the test pins 200 include the symmetrical first and second structures 210 and 220 with respect to the axis AX, the test pins 200 may be flipped about the axis AX after the reliability test is completed. In such a case, the test pins 200 may contact the substrate pads 110 through the second structure 220, and the test substrate 100 may be electrically connected to another semiconductor device to perform the next reliability test.

Since the test pins 200 perform the reliability test on different semiconductor devices, the same test pins 200 may be reused for multiple tests. As a result, manufacturing time and cost for producing the test pins 200 may be reduced, and process efficiency may be improved.

In addition, the first and second elastic structures 310 and 320 may respectively extend along the test pins 200. The first elastic structure 310 may prevent misalignment between the test pins 200, and the second elastic structure 320, disposed between the test pins 200 and the test substrate 100, may absorb external forces applied to the pins and improve the accuracy of the reliability test.

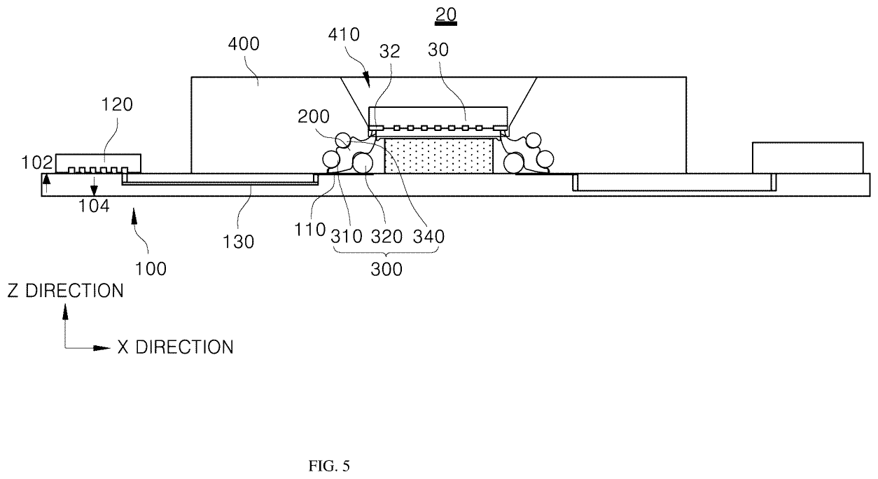

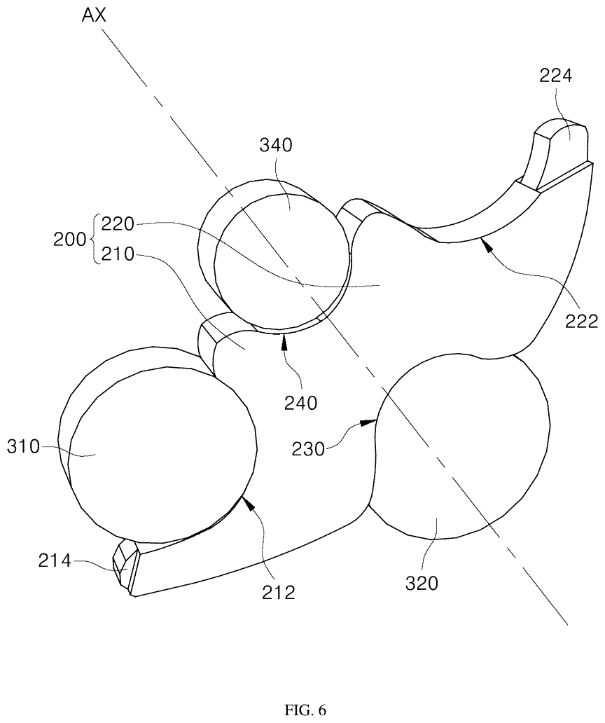

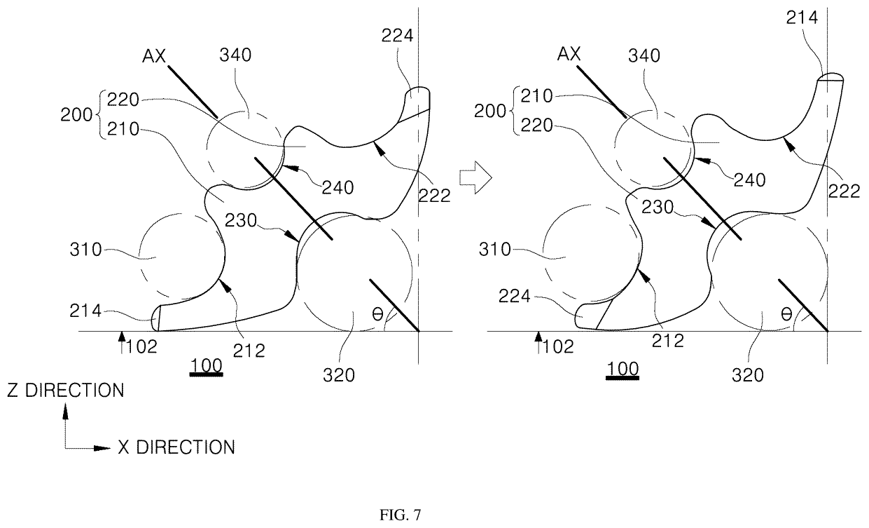

FIG. 5 is a cross-sectional view illustrating a semiconductor device testing equipment in accordance with example embodiments. FIG. 6 is a perspective view illustrating a test pin and a plurality of elastic structures. FIG. 7 is a view illustrating a reusable test pin and a plurality of elastic structures. The semiconductor device testing equipment may be substantially the same as or similar to the semiconductor device testing equipment described with reference to FIGS. 1 to 4 except for a configuration of the plurality of test pins. Thus, same or similar components are denoted by the same or similar reference numerals, and repeated descriptions of the same components will be omitted.

Referring to FIGS. 5 to 7, the semiconductor device testing equipment 20 may include a test substrate 100 having a plurality of substrate pads 110, a plurality of test pins 200 respectively disposed on the substrate pads 110, and a plurality of elastic structures 300 extending along the test pins 200. The plurality of elastic structures 300 may include a first elastic structure 310 and a second elastic structure 320, and may further include a fourth elastic structure 340.

In exemplary embodiments, the plurality of test pins 200 may be provided on the test substrate 100. The test pins 200 may be respectively disposed on the substrate pads 110 of the test substrate 100. The test pins 200 may support a semiconductor device 30, which is the subject of the reliability test, on the test substrate 100.

In exemplary embodiments, each of the test pins 200 may include a first structure 210 and a second structure 220 extending from the first structure 210. The first structure 210 and the second structure 220 may constitute the test pin. Each of the test pins 200 may be inclined with respect to a first surface 102 of the test substrate 100 to have a predetermined inclination angle θ.

In exemplary embodiments, the test pins 200 may each include a third groove 230 provided on the axis AX along which the first structure 210 and the second structure 220 extend. The test pins 200 may also include fourth grooves 240 disposed opposite to the third grooves 230 along the axis AX. When the test pins 200 include the fourth grooves 240, the test pins 200 may be referred to as manta pins.

The third grooves 230 may fix the second elastic structure 320 during the first and second reliability tests. The third grooves 230 may fix the second elastic structure 320 between the test pins 200 and the test substrate 100. The fourth grooves 240 may fix a fourth elastic structure 340 during the first and second reliability tests.

The fourth grooves 240 may be provided symmetrically with respect to the axis AX. The test pins 200 may be arranged along the substrate pads 110 of the test substrate 100, and the fourth elastic structure 340 may be fixed through the fourth grooves 240 during the first and second reliability tests.

The fourth grooves 240 of the test pins 200 may have a shape corresponding to the fourth elastic structure 340. The fourth grooves 240 may fix the fourth elastic structure 340 through the corresponding shape. The fourth grooves 240 may be provided to face upward, opposite to the test substrate 100. For example, the fourth groove 240 may include a circular groove shape, and may alternatively include a triangular, rectangular, or pentagonal groove shape without limitation.

The fourth elastic structure 340 may extend along the fourth grooves 240 of the test pins 200. The fourth elastic structure 340 may extend along the fourth grooves 240 during the first and second reliability tests. The fourth elastic structure 340 may be fixed by the fourth grooves 240 during the first and second reliability tests. The fourth elastic structure 340 may be provided to be compressed between the test pins 200 and the frame 400 during the first and second reliability tests.

The fourth elastic structure 340 may have elasticity. Due to this elasticity, even when the test pins 200 are pressed by the semiconductor device 30 or the frame 400, the fourth elastic structure 340 may buffer the rotational force generated between the test pins 200 together with the first elastic structure 310 and stably support the test pins 200.

Since the fourth elastic structure 340 and the third elastic structure 330 are fixed to the fourth groove 240 and the third groove 230, respectively, in symmetrical positions with respect to the axis AX, they may reliably support the test pins 200. Since the first structure 210 and the second structure 220 are symmetrical with respect to the axis AX, the fourth and third elastic structures 340 and 330 provided along the axis AX may stably distribute forces applied to the test pins 200 and support them reliably. For example, a diameter of the fourth elastic structure 340 may be in a range of 0.5 mm to 1.2 mm.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor device testing equipment, comprising:
a test substrate having a first surface and a second surface opposing each other, and a plurality of substrate pads disposed on the first surface;
a plurality of test pins respectively disposed on the plurality of substrate pads and supporting a semiconductor device, each of the test pins having first and second structures that are symmetrical with respect to an axis having a predetermined inclination from the first surface of the test substrate; and
first to third elastic structures respectively extending along the plurality of test pins.

2. The semiconductor device testing equipment of claim 1, wherein the predetermined inclination is within a range of 30 degrees to 60 degrees.

3. The semiconductor device testing equipment of claim 1, wherein each of the plurality of test pins includes a first pattern provided on the first structure, and a second pattern provided on the second structure and different from the first pattern.

4. The semiconductor device testing equipment of claim 1, wherein each of the first to third elastic structures has a diameter within a range of 0.5 mm to 1.2 mm.

5. The semiconductor device testing equipment of claim 1, wherein the semiconductor device is formed by a lead-type packaging process.
